(19) United States
(12) Patent Application Publication
(10) Pub. No.: US 2005/0118334 A1
(43) Pub. Date: Jun. 2, 2005

(54) PROCESS FOR INHIBITING SRZ FORMATION AND COATING SYSTEM THEREFOR

(75) Inventors: Mark Daniel Gorman, West Chester, OH (US); Ramgopal (NMN) Darolia, West Chester, OH (US); Robert William Bruce, Oveland, OH (US)

Correspondence Address: HARTMAN AND HARTMAN, P.C., 552 EAST 700 NORTH, VAIPARAISO, IN, 46383, US

(73) Assignee: GENERAL ELECTRIC COMPANY, Schenectady, NY (US)

(21) Appl. No.: 10/711,240

(22) Filed: Sep. 3, 2004

(51) Int. Cl. C23C 16/00

(52) U.S. Cl. 427/252; 427/402

(57) ABSTRACT

A process for reducing the incidence of a secondary reaction zone (SRZ) in alloys prone to SRZ formation, particularly superalloys that have a high refractory element content. The process finds use with articles having a wall region that defines external and internal surfaces on the exterior and within the article, respectively. Diffusion coatings are formed on the internal and external surfaces of the article, with at least the diffusion coating on the external surface comprising an additive layer and a diffusion zone that is beneath the additive layer and extends into the wall region. The additive layer and at least a portion of the diffusion zone of the external diffusion coating is then removed to define an exposed surface region on the exterior of the article. An overlay coating is then deposited on the exposed surface region.

### BACKGROUND OF THE INVENTION

The present invention generally relates to protective coating systems for components exposed to high temperatures, such as the hostile thermal environment of a gas turbine engine. More particularly, this invention relates to a process for inhibiting the formation of a secondary reaction zone (SRZ) in a substrate on which such a coating system is deposited.

Certain turbine, combustor and augmentor components of gas turbine engines are susceptible to damage by oxidation and hot corrosion attack, and are therefore protected by an environmental coating and optionally a thermal barrier coating (TBC), in which case the environmental coating is termed a bond coat. In combination, the TBC and bond coat form what has been termed a TBC system.

Environmental coatings and TBC bond coats are often formed of an oxidation-resistant aluminum-containing alloy or intermetallic. An example of the former is MCrAlX (where M is iron, cobalt and/or nickel, and X is yttrium or another rare earth element), which is deposited as an overlay coating. An example of the latter includes diffusion coatings, particular diffusion aluminides and platinum-aluminides (PtAl) that contain aluminum intermetallics (e.g., NiAl and PtAl). Other types of environmental coatings and bond coats that have been proposed include beta-phase nickel aluminide (NiAl) overlay coatings. In contrast to the aforementioned MCrAlX overlay coatings, which are metallic solid solutions containing intermetallic phases, the NiAl beta phase is an intermetallic compound that exists for nickel-aluminum compositions containing about 30 to about 60 atomic percent aluminum. Notable examples of beta-phase NiAl coating materials are disclosed in commonly-assigned U.S. Pat. No. 5,975,852 to Nagaraj et al., U.S. Pat. No. 6,153,313 to Rigney et al., U.S. Pat. No. 6,255,001 to Darolia, and U.S. Pat. No. 6,291,084 to Darolia et al. These NiAl compositions, which preferably contain a reactive element (such as zirconium and/or hafnium) and/or other alloying constituents (such as chromium), have been shown to improve the adhesion of a ceramic TBC, thereby increasing the spallation resistance of the TBC. These same compositions can also be used alone as environmental coatings for superalloy components that do not require the thermal protection of a TBC.

TBC systems and environmental coatings are being used in an increasing number of turbine applications (e.g., combustors, augmentors, turbine blades, turbine vanes, etc.). The material systems used for most turbine airfoil applications comprise a nickel-base superalloy as the substrate material, a diffusion platinum aluminide (PtAl) as the bond coat, and a zirconia-based ceramic as the thermally-insulating TBC material. A notable example of a PtAl bond coat composition is disclosed in U.S. Pat. No. 6,066,405 to Schaeffer. Yttria-stabilized zirconia (YSZ), with a typical yttria content in the range of about 3 to about 20 weight percent, is widely used as the ceramic material for TBC's. Improved spallation resistance can be achieved by depositing the TBC by electron-beam physical vapor deposition (EB-PVD) to have a columnar grain structure.

Approaches proposed for further improving the spallation resistance of TBC's are complicated in part by the compositions of the underlying superalloy and interdiffusion that occurs between the superalloy and the bond coat. For example, the above-noted bond coat materials contain relatively high amounts of aluminum relative to the superalloys they protect, while superalloys contain various elements that are not present or are present in relatively small amounts in bond coats. During bond coat deposition, a “primary diffusion zone” of chemical mixing occurs to some degree between the coating and the superalloy substrate as a result of the concentration gradients of the constituents. At elevated temperatures, further interdiffusion occurs as a result of solid-state diffusion across the substrate/coating interface. The migration of elements across this interface alters the chemical composition and microstructure of both the bond coat and the substrate in the vicinity of the interface, generally with deleterious results. For example, migration of aluminum out of the bond coat reduces its oxidation resistance, while the accumulation of aluminum in the substrate beneath the bond coat can result in the formation of topologically close-packed (TCP) phases that, if present at sufficiently high levels, can drastically reduce the load-carrying capability of the alloy. These detrimental effects occur whether the coating is used as a bond coat for a TBC, or alone as an environmental coating.

Certain high strength superalloys contain significant amounts of refractory elements, such as rhenium, tungsten, tantalum, hafnium, molybdenum, niobium, and zirconium. If present in sufficient amounts or combinations, these elements can reduce the intrinsic oxidation resistance of a superalloy and, following deposition of an aluminum-containing coating, promote the formation of a secondary reaction zone (SRZ) in which deleterious TCP phases form. An example of such a superalloy is commercially known as MX4, a fourth generation single-crystal superalloy disclosed in commonly-assigned U.S. Pat. No. 5,482,789. Other notable examples of high-refractory superalloys include single-crystal superalloys commercially known under the names René N6 (U.S. Pat. No. 5,455,120), PWA1484, CMSX-4, CMSX-10, and CMSX-12, each of which has the potential for being prone to SRZ. While there has been an ongoing effort to develop heat treatments, pre-coat surface preparations, and coating systems that substantially reduce or eliminate the formation of SRZ in high-refractory alloys coated with aluminum-containing coatings, further advancements are desired.

### BRIEF SUMMARY OF THE INVENTION

The present invention provides a process for significantly reducing the incidence of SRZ in alloys prone to SRZ formation, particularly superalloys that have a high refractory element content.

The process finds use with articles having a wall region that defines external and internal surfaces on the exterior and within the article, respectively. Diffusion coatings are formed on the internal and external surfaces of the article, with at least the diffusion coating on the external surface comprising an additive layer and a diffusion zone that is beneath the additive layer and extends into the wall region. The additive layer and preferably a majority of the diffusion zone of the external diffusion coating is then removed to define an exposed surface region on the exterior of the article. An overlay coating is then deposited on the exposed surface region. According to the invention, the diffusion zone is sufficiently removed to inhibit formation of SRZ in the exposed surface region.

A significant aspect of this invention is the ability to reduce the incidence of SRZ in superalloys having a high refractory element content. For example, the present invention has been demonstrated with the MX4 alloy, whose tantalum, tungsten, molybdenum, and rhenium contents render the alloy susceptible to SRZ formation when the alloy is heated during process and subsequent high temperature exposures. The invention is also compatible with overlay coatings of the type used as bond coats for ceramic thermal barrier coatings (TBC's), outer coatings to decrease the thermal conductivity of the coating system, inhibit erosion, increase resistance to CMAS-related spallation, and diffusion barrier coatings to reduce interdiffusion between diffusion coatings and the substrates on which they are deposited.

Other objects and advantages of this invention will be better appreciated from the following detailed description.

### BRIEF DESCRIPTION OF THE DRAWINGS

FIG. 1 is a perspective view of a high pressure turbine blade.

FIG. 2 is a cross-sectional representation of a wall region of the blade of FIG. 1, wherein a TBC system is on an external surface of the wall region and a diffusion coating is on an internal surface of the wall region in accordance with an embodiment of this invention.

FIGS. 3 and 4 depict a preferred processing sequence for forming the TBC system of FIG. 2.

### DETAILED DESCRIPTION OF THE INVENTION

The present invention is intended for use on components that require coatings for protection from their operating environment. Notable examples of such components include the high and low pressure turbine nozzles and blades, shrouds, combustor liners and augmentor hardware of gas turbine engines. An example of a high pressure turbine blade 10 is shown in FIG. 1. The blade 10 generally includes an airfoil 12 against which hot combustion gases are directed during operation of the gas turbine engine, and whose surface is therefore subjected to severe attack by oxidation, corrosion and erosion. The airfoil 12 is anchored to a turbine disk (not shown) with a dovetail 14 formed on a root section 16 of the blade 10. Cooling holes 18 are present in the airfoil 12 through which bleed air flowing through internal passages (not shown) within the blade 10 exits to transfer heat from the blade 10. While the advantages of this invention will be described with reference to components of a gas turbine engine, such as the high pressure turbine blade 10 shown in FIG. 1, the teachings of this invention are generally applicable to other components that have an internal cavity and can benefit from a protective coating system.

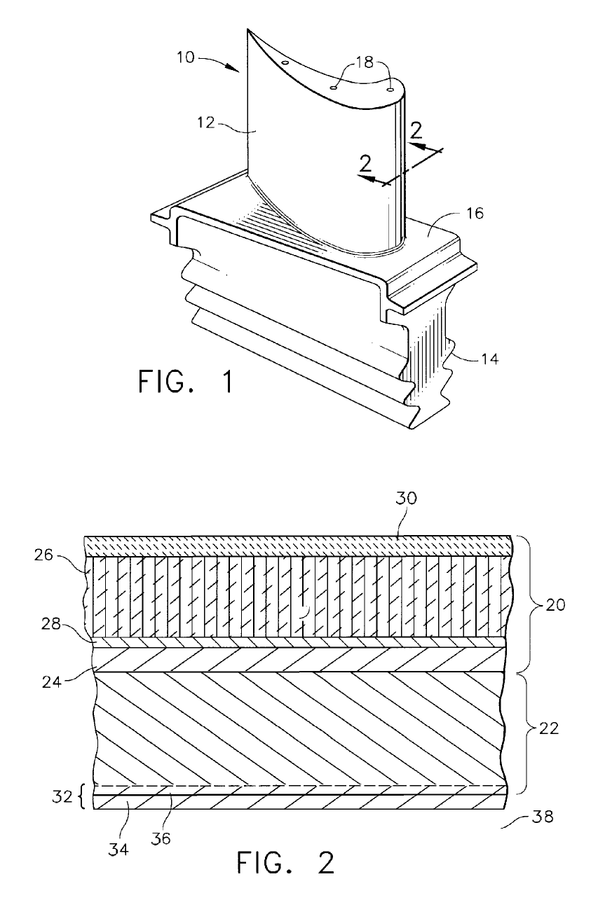

Represented in FIG. 2 is a wall 22 of the blade 10 whose outer (external) surface is protected by a thermal barrier coating (TBC) system 20 in accordance with an embodiment of the present invention. The wall 22 also defines an internal surface that, with other internal surfaces within the blade 10, forms an internal cooling passage 38, e.g., for cooperation with the cooling holes 18 in FIG. 1. As shown, the TBC system 20 includes a bond coat 24 deposited on the external surface of the wall 22. The bond coat 24 adheres a thermal-insulating ceramic layer 26, or TBC, to the substrate 22. As will be discussed in greater detail below, the bond coat 24 is an aluminum-containing overlay coating, and is depicted in FIG. 2 as having a thermally grown oxide (TGO) scale 28, generally aluminum oxide (alumina), that promotes adhesion of the TBC 26 to the bond coat 24. The TBC 26 is portrayed as having a strain-tolerant columnar grain structure obtained by depositing the TBC 26 using a physical vapor deposition (PVD) technique known in the art (e.g., EB-PVD), though a plasma spray technique such as air plasma spraying (APS) could be used to deposit a noncolumnar ceramic layer. A preferred material for the TBC 26 is an yttria-stabilized zirconia (YSZ), though other ceramic materials could be used such as yttria, nonstabilized zirconia, or zirconia stabilized by magnesia, ceria, scandia, and/or other oxides. Finally, FIG. 2 shows an optional outer coating layer 30 overlying the TBC 26. The composition and function of the outer coating layer 30 will be discussed below.

Because the wall 22 is subject to corrosion and oxidation as a result of the cooling air flowing through the passage 38, the internal surface of the wall 22 is protected by a coating, depicted in FIG. 2 as a diffusion coating 32 and more preferably and particularly a diffusion aluminide coating 32. As is typical with diffusion coatings, the aluminide coating 32 comprises an additive layer 34 overlying a diffusion zone 36 that extends below the original internal surface. The aluminide coating 32 has an environmentally-resistant composition formed by a diffusion process, such as vapor phase (gas phase) aluminiding (VPA), or chemical vapor deposition (CVD), by which an aluminum-containing vapor is flowed through the internal passage 38 to react the internal surface. The additive layer 34 contains the environmentally-resistant intermetallic phase MAl, where M is iron, nickel and/or cobalt, depending on the substrate material and whether additional elements were predeposited or co-deposited on the internal surface, such as platinum, chromium, silicon, rhodium, hafnium, yttrium, and zirconium. A typical thickness range for the additive layer is about 20 to 50 micrometers. The diffusion zone 36 typically extends about 15 to 50 micrometers into the wall 22 and contains various intermetallic and metastable phases that form during the coating reaction as a result of diffusional gradients and changes in elemental solubility in the local region of the substrate. During high temperature exposure in air, the additive layer 34 forms a protective alumina scale (similar to the alumina scale 28) that inhibits oxidation of the diffusion coating 32 and the underlying wall 22.

The service life of the TBC system 20 is typically limited by a spallation event driven by bond coat oxidation and thermal fatigue resulting from the CTE mismatch between the ceramic material of the TBC 20 and the underlying metallic substrate (bond coat 24 and wall 22). Improved spallation resistance has been achieved with overlay bond coats of beta-phase nickel aluminide (NiAl), as disclosed in the aforementioned U.S. Pat. Nos. 5,975,852, 6,153,313, 6,255,001, and 6,291,084. Preferred NiAl compositions contain, in atomic percent, about 30% to about 60% aluminum, optionally up to about 10% chromium, and 0.1% to about 1.2% of one or more reactive elements such as zirconium, hafnium, silicon, yttrium, and titanium, with the balance being essentially nickel. The beta-phase NiAl overlay bond coat 24 can be deposited by various physical vapor deposition processes, including EB-PVD, cathodic arc physical vapor deposition, ion plasma deposition (IPD), and thermal spray.

TBC's of the type shown in FIG. 2 are also susceptible to spallation induced by contamination with compounds present in the hot gas path of a gas turbine engine during its operation. Notable contaminants include such oxides as calcia, magnesia, alumina and silica, which when present together at elevated temperatures form a compound referred to herein as CMAS. CMAS has a relatively low melting eutectic (about 1227° C.) that when molten is able to infiltrate to the cooler subsurface regions of a TBC, where it resolidifies. During thermal cycling, a CTE mismatch between CMAS and the TBC 26 promotes spallation, particularly if the TBC 26 was deposited by PVD and APS due to the ability of the molten CMAS to penetrate the columnar and porous grain structures, respectively, of PVD and APS TBC's.

To reduce its vulnerability to spallation from contamination by CMAS and other potential contaminants, the TBC 26 is protected by the outer coating layer 30, whose composition can be tailored to be resistant to infiltration by CMAS and other potential high-temperature contaminants. For example, the outer coating layer 30 can be formed of a material capable of interacting with molten CMAS to form a compound with a melting temperature that is significantly higher than CMAS, so that the reaction product of CMAS and the additional ceramic material does not melt and does not infiltrate the TBC 26. Examples of CMAS-resistant coatings include alumina, alumina-containing YSZ, and hafnia-based ceramics disclosed in commonly-assigned U.S. Pat. Nos. 5,660,885, 5,683,825, 5,871,820, 5,914,189, and 6,627,323 and commonly-assigned U.S. patent application Ser. Nos. 10/064,939 and 10/073,564, whose disclosures regarding CMAS-resistant coating materials are incorporated herein by reference. Suitable thicknesses for a CMAS-resistant outer coating layer 30 is about 2 to about 50 micrometers.

Alternatively or in addition, the outer coating layer 30 could be formulated to have erosion and/or impact resistance better than the underlying TBC 26. Examples of suitable materials for this purpose include certain of the above-noted CMAS-resistant materials, particularly alumina as reported in U.S. Pat. No. 5,683,825 and U.S. patent application Ser. No. 10/073,564. Other erosion and impact-resistant compositions include reduced-porosity YSZ as disclosed in commonly-assigned U.S. patent application Ser. Nos. 10/707,197 and 10/708,020, fully stabilized zirconia (e.g., ≧17% YSZ) as disclosed in commonly-assigned U.S. patent application Ser. No. 10/708,020, and chemically-modified zirconia-based ceramics. A CMAS-resistant layer can be deposited on an erosion and impact-resistant layer, or a single layer can perform the role of the CMAS-resistant layer and the erosion and impact-resistant layer. Suitable thicknesses for an erosion-resistant outer coating layer 30 is about 4 to about 15 micrometers, or about 6 to about 50 micrometers if the outer coating layer 30 is also CMAS-resistant.

Another option is to form the outer coating layer 30 of a material having a lower coefficient of thermal conductivity than the TBC 26, preferably at least 20% lower than 7% YSZ in the same condition. Notably, zirconia-based ceramics with conductivities lower than 7YSZ are disclosed in commonly-assigned U.S. Pat. No. 6,586,115 to Rigney et al., U.S. Pat. No. 6,686,060 to Bruce et al., commonly-assigned U.S. patent application Ser. Nos. 10/063,962 to Bruce, Ser. No. 10/064,785 to Darolia et al., and Ser. No. 10/064,939 to Bruce et al., and U.S. Pat. No. 6,025,078 to Rickerby. A low-conductivity outer coating layer 30 may have a columnar grains structure similar to the TBC 26 or a noncolumnar grain structure of the type resulting from deposition a thermal spraying (e.g., APS). Because the adhesion of low-conductivity compositions can be less than that of 6-8% YSZ, it may be desirable to formulate the TBC 26 as an adhesion layer for the outer coating layer 30. For example, the TBC 26 can be 3-11% YSZ such as disclosed in commonly-assigned U.S. patent application Ser. Nos. 10/707,197 and 10/708,020, or a zirconia-based ceramic with equivalent phase stability. A suitable thickness for and adhesion-promoting TBC 26 is about 5 to about 50 micrometers.

According to a preferred aspect of this invention, the above-described coating systems provide excellent environmental and thermal protection for a variety of superalloys, notably certain alloys prone to SRZ formation as a result interdiffusion between the high refractory content of these alloys and the aluminum content of the bond coat 24 and aluminide coating 32. Susceptibility to the formation of SRZ containing deleterious TCP phases is believed to be especially likely in single-crystal nickel-based superalloys that contain about 6.5 weight percent or more of tantalum, about 5 weight percent or more of tungsten, about 2 weight percent or more of molybdenum, and/or about 3 weight percent or more of rhenium. A feature of the present invention is to reduce the incidence of SRZ in SRZ-prone alloys, examples of which include the aforementioned MX4, René N6, PWA1484, CMSX-4, CMSX-10, and CMSX-12 alloys.

As disclosed in U.S. Pat. No. 5,482,789, the MX4 superalloy contains, by weight, about 0.4% to about 6.5% ruthenium, about 5.8% to about 10.7% tantalum, about 3.0% to about 7.5% tungsten, about 0.9% to about 2.0% molybdenum, about 4.5% to about 5.75% rhenium, up to about 0.15% hafnium, about 4.25% to about 17.0% cobalt, about 1.25% to about 6.0% chromium, about 5.0% to about 6.6% aluminum, up to about 0.06% carbon, up to about 0.01% boron, up to about 0.02% yttrium, up to about 1.0% niobium, up to about 1.0% titanium, a molybdenum+chromium+niobium content of about 2.15% to about 9.0%, an aluminum+titanium+tungsten of about 8.0% to about 15.1%, and the balance nickel and incidental impurities. As disclosed in U.S. Pat. No. 5,455,120, the N6 alloy has a composition of, by weight, about 10 to about 15% cobalt, about 4.0 to about 6% chromium, about 0.5 to about 2.0% molybdenum, the combination of Cr+Mo from about 4.6 to about 6.5%, about 7 to less than 9.25% tantalum, about 5 to less than 6.25% aluminum, about 5 to about 6.5% tungsten, about 5.1 to about 5.6% rhenium, about 0.1 to about 0.5% hafnium, about 0.02 to about 0.07% carbon, about 0.003 to about 0.01% boron, up to about 0.03% yttrium, up to about 6% ruthenium, up to about 1% niobium, with the balance nickel and incidental impurities. In preferred embodiments of this invention, the TBC system 20 on a component formed of MX4 has an overlay bond coat 24 of beta-phase NiAlCrZr, an adhesion layer of 6-8% YSZ combined with a thermal insulating layer having a thermal conductivity of not more than 80% of 7% YSZ (TBC 26), and an alumina-based CMAS-resistant outer layer 30, and the TBC system 20 on a component formed of René N6 has an overlay bond coat 24 of beta-phase NiAlCrZr, a TBC 26 having thermal conductivity of not more than 85% of 7% YSZ, and an alumina-based CMAS-resistant outer layer 30. However, these preferred TBC systems 20 form TCP-containing SRZ because of the high refractory element content of the MX4 and N6 alloys, with the result that the rupture strength, ductility and fatigue resistance of the alloys are reduced.

Because SRZ occurs in the regions of the wall 22 in which interdiffusion occurs with the bond coat 24 and diffusion coating 32, efforts have been previously undertaken to develop diffusion barrier coatings that will inhibit interdiffusion. For example, diffusion barrier coatings in the form of a carburized layer, nitrided layer, and Ru-containing coatings are disclosed in commonly-assigned U.S. Pat. Nos. 5,598,968 and 5,891,267, U.S. Pat. No. 6,447,932, and U.S. patent application Ser. No. 10/605,860, respectively. While these coatings are effective, additional coatings and coating processes are not always practical or possible.

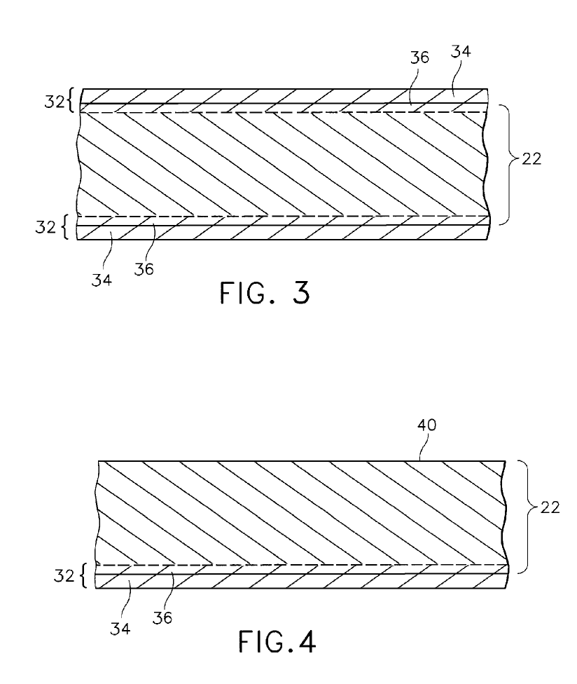

The present invention is to perform certain processing steps that inhibit the formation of SRZ, whether used alone or in combination with previous SRZ-inhibiting coatings and processing steps. According to this invention, SRZ-formation is inhibited by depositing and then removing a diffusion coating on the external surface of the wall 22 prior to deposition of the TBC system 20, and particularly the overlay bond coat 24. This process is represented in FIGS. 3 and 4, in which a diffusion coating 32 on the exterior surface of the wall 22 in FIG. 3 has been removed in FIG. 4. The entire diffusion coating 32 is preferably removed as shown; alternatively, the additive layer 34 and at least a significant portion of the diffusion zone 36 are removed before depositing the overlay bond coat 24. The external diffusion coating 32 is preferably co-deposited with the diffusion coating 32 on the internal surface, though it is foreseeable that these coatings 32 could be deposited separately of different materials. Removal of the diffusion coating 32 from the external surface can be performed in any suitable manner, such as contacting the diffusion coating 32 with an acidic stripping solution containing nitric acid (HNO₃) or a mixture of hydrochloric acid (HCl) and phosphoric acid (H₃PO₄) at a temperature of about 50 to about 150° F. (about 10 to about 65° C.) for a duration of about one to six hours.

As represented in FIGS. 3 and 4, a preferred process sequence for this invention involves simultaneously diffusion aluminiding the internal and external surfaces of the wall 22 to produce the diffusion aluminide coatings 32 shown in FIG. 3. Each of the coatings 32 can be seen to have an additive layer 34 and a diffusion zone 36 beneath the additive layer 34 and extending into the wall 22. Then, and without removing the diffusion aluminide coating 32 on the internal surface of the wall 22, at least a portion of the diffusion aluminide coating 32 on the external surface is removed, namely, its additive layer 34 and at least a significant portion of its diffusion zone 36, preferably the entire diffusion zone 36. Removal of the internal diffusion aluminide coating 32 can be can be avoided by masking the surfaces of the internal passage 38 with any suitable maskant known in the art for this purpose, such as a photoresist, wax, lacquer, etc. As a result of the stripping operation, a surface region 40 of the wall 22 is exposed on the exterior of the wall 22 and on which the overlay bond coat 24 can be deposited. Thereafter, the bond coat 24 is deposited by PVD, etc, followed by the TBC 26 and any additional coating layers such as the outer coating layer 30.

An additional benefit of the above-described process is that both the internal and external surfaces of the wall can be protected by coatings without any detriment to the coatings. In particular, it has been determined that the performance of a beta-phase NiAl coating deteriorates if the coating has been deposited on a diffusion aluminide coating or overcoated with a diffusion aluminide coating. By allowing the aluminiding of the external wall surface during aluminiding of its internal surface, and then removing the external diffusion aluminide coating 32 before depositing the beta-phase NiAl overlay bond coat 24, the benefits include reduced SRZ formation and maintained performance of the bond coat 24. According to the invention, a reduction in SRZ formation is attained with the above-described, even though a diffusion aluminide coating 32 remains on the internal surface of the wall 22, because of the much lower temperatures (e.g., less than 1800° F. (980° C.)) seen within the internal passage 38, such that this surface region of the wall 22 is not prone to SRZ formation.

While the invention has been described in terms of particular embodiments, it is apparent that other forms could be adopted by one skilled in the art. Therefore, the scope of the invention is to be limited only by the following claims.

1. A process of coating an article having a wall region defining an external surface on an exterior of the article and an oppositely-disposed internal surface within the article, the process comprising the steps of:
forming diffusion coatings on the internal and external surfaces of the article, the diffusion coating on the external surface comprising an additive layer and a diffusion zone that is beneath the additive layer and extends into the wall region;
removing the additive layer and at least a portion of the diffusion zone of the diffusion coating on the external surface of the article so as to define an exposed surface region on the exterior of the article; and then
depositing an overlay coating on the exposed surface region;
wherein the portion of the diffusion zone removed is sufficient to inhibit formation of a secondary reaction zone in the exposed surface region.

2. The process according to claim 1, wherein the diffusion coatings are simultaneously formed on the internal and external surfaces of the article.

3. The process according to claim 1, wherein the diffusion coatings are diffusion aluminide coatings.

4. The process according to claim 3, wherein substantially all of the diffusion zone is removed during the removing step.

5. The process according to claim 1, wherein the overlay coating consists essentially of intermetallic phases.

6. The process according to claim 5, wherein the overlay coating consists essentially of beta-phase NiAl intermetallic containing, in atomic percent, about 30% to about 60% aluminum, optionally up to about 10% chromium, 0.1% to about 1.2% of at least one element chosen from the group consisting of zirconium, hafnium, silicon, yttrium, and titanium, the balance being essentially nickel.

7. The process according to claim 1, wherein the overlay coating is an aluminum-containing bond coat, the process further comprising the step of depositing a ceramic coating on the bond coat.

8. The process according to claim 7, wherein the ceramic coating comprises yttria-stabilized zirconia.

9. The process according to claim 7, further comprising the step of depositing on the ceramic coating a coating layer that exhibits in comparison to the ceramic coating at least one property chosen from the group consisting of increased erosion resistance and increased resistance to infiltration of CMAS.

10. The process according to claim 7, further comprising the step of depositing on the ceramic coating a coating layer that has lower thermal conductivity than the ceramic coating.

11. The process according to claim 1, further comprising the step of depositing on at least the external surface a barrier layer prior to forming the diffusion coatings, the barrier layer inhibiting interdiffusion between the diffusion coatings and the wall region.

12. The process according to claim 1, wherein the wall region is formed of an alloy containing at least one refractory metal selected from the group consisting of about 6.5 weight percent or more of tantalum, about 5 weight percent or more of tungsten, about 2 weight percent or more of molybdenum, and about 3 weight percent or more of rhenium.

13. The process according to claim 12, wherein the superalloy consists of, by weight, 0.4% to 6.5% ruthenium, 4.5% to 5.75% rhenium, 5.8% to 10.7% tantalum, 4.25% to 17.0% cobalt, up to 0.05% hafnium, up to 0.06% carbon, up to 0.01% boron, up to 0.02% yttrium, 0.9% to 2.0% molybdenum, 1.25% to 6.0% chromium, up to 1.0% niobium, 5.0% to 6.6% aluminum, up to 1.0% titanium, 3.0% to 7.5% tungsten, and wherein the sum of molybdenum plus chromium plus niobium is 2.15% to 9.0%, and wherein the sum of aluminum plus titanium plus tungsten is 8.0% to 15.1%, the balance nickel and incidental impurities.

14. The process according to claim 12, wherein the superalloy consists of, by weight, about 10 to about 15% cobalt, about 4.0 to about 6% chromium, about 0.5 to about 2.0% molybdenum, the combination of Cr+Mo from about 4.6 to about 6.5%, about 7 to less than 9.25% tantalum, about 5 to less than 6.25% aluminum, about 5 to about 6.5% tungsten, about 5.1 to about 5.6% rhenium, about 0.1 to about 0.5% hafnium, about 0.02 to about 0.07% carbon, about 0.003 to about 0.01% boron, up to about 0.03% yttrium, up to about 6% ruthenium, up to about 1% niobium, with the balance nickel and incidental impurities.

15. A process of coating an article having a wall region formed of an alloy that is susceptible to formation of a secondary reaction zone as a result of containing at least one refractory metal selected from the group consisting of about 6.5 weight percent or more of tantalum, about 5 weight percent or more of tungsten, about 2 weight percent or more of molybdenum, and about 3 weight percent or more of rhenium, the wall region defining an external surface on an exterior of the article and an oppositely-disposed internal surface within the article, the process comprising the steps of:
simultaneously forming diffusion aluminide coatings on the internal and external surfaces of the article, each of the diffusion aluminide coatings comprising an additive layer and a diffusion zone that is beneath the additive layer and extends into the wall region;
without removing the diffusion aluminide coating on the internal surface of the article, removing the additive layer and substantially all of the diffusion zone of the diffusion aluminide coating on the external surface of the article so as to define an exposed surface region on the exterior of the article; and then
depositing on the exposed surface region an overlay coating consisting essentially of beta-phase NiAl intermetallic;
wherein the portion of the diffusion zone removed is sufficient to inhibit formation of the secondary reaction zone in the exposed surface region.

16. The process according to claim 15, wherein the overlay coating consists of, in atomic percent, about 30% to about 60% aluminum, optionally up to about 10% chromium, 0.1% to about 1.2% of at least one element chosen from the group consisting of zirconium, hafnium, silicon, yttrium, and titanium, the balance nickel and incidental impurities.

17. The process according to claim 15, further comprising the step of depositing a ceramic coating on the overlay coating.

18. The process according to claim 16, wherein the ceramic coating comprises yttria-stabilized zirconia.

19. The process according to claim 16, further comprising the step of depositing on the ceramic coating a coating layer that exhibits in comparison to the ceramic coating at least one property chosen from the group consisting of increased erosion resistance, increased resistance to infiltration of CMAS, and lower thermal conductivity.

20. The process according to claim 15, further comprising the step of depositing on at least the external surface a barrier layer prior to forming the diffusion aluminide coatings, the barrier layer inhibiting interdiffusion between the diffusion aluminide coatings and the wall region.
